(19) United States
(12) Patent Application Publication
(10) Pub. No.: US 2013/0186144 A1
(43) Pub. Date: Jul. 25, 2013

(54) ELECTROMAGNETIC CASTING METHOD OF SILICON INGOT

(71) Applicants: Shinichi Miyamoto, Tokyo (JP); Mitsuo Yoshihara, Tokyo (JP)

(72) Inventors: Shinichi Miyamoto, Tokyo (JP); Mitsuo Yoshihara, Tokyo (JP)

(21) Appl. No.: 13/793,167

(22) Filed: Mar. 11, 2013

(30) Foreign Application Priority Data
Sep. 3, 2010 (JP) 2010-198053

(51) Int. Cl. H01L 31/18

(52) U.S. Cl. CPC H01L 31/182
USPC 65/90

(57) ABSTRACT

Disclosed is an electromagnetic casting method of a silicon ingot in which a polycrystalline silicon ingot is continuously cast by charging silicon raw materials into a bottomless cold copper mold, melting the charged silicon raw materials through electromagnetic induction, pulling down to solidify the molten silicon, in which the length of a part of copper mold positioned below a lower end of an induction coil surrounding the copper mold is set to more than 40 mm and 180 mm or less. According to this method, a copper contamination of a silicon ingot incurred by a copper cold mold can be suppressed to produce a silicon ingot which is suitable as a starting material of the substrate of a solar cell.

### BACKGROUND OF THE INVENTION

1. Field of the Invention

The present invention relates to a method for producing a polycrystalline silicon ingot by applying a continuous casting technique through electromagnetic induction, more specifically, a method for producing a silicon ingot which is suitable as a starting material of the substrate material of a solar cell by suppressing a copper contamination of the silicon ingot incurred by a cold copper mold.

2. Description of the Related Art

According to a continuous casting method through electromagnetic induction (hereinafter, referred to as “an electromagnetic casting method”), since a molten material (molten silicon in this case) and a mold are almost non-contact with each other, an ingot free of impurity contamination can be produced. Further, a significant reduction of production cost can be achieved owing to an advantage that no high purity material is required as a mold material due to no contamination from the mold and also owing to a continuous casting capability. Therefore, an electromagnetic casting method has conventionally been applied for production of polycrystalline silicon to be used as a substrate material of a solar cell.

In the electromagnetic casting method, a bottomless cold mold (or crucible) formed by arranging electrically- and thermally-conductive material (typically, using copper) in strips inside a high-frequency induction coil is used, the strips being electrically isolated from each other in a circumferential direction and inside of which is cooled with water. For the coil and a portion surrounded by the strips and serving as a bottomless mold, each may be either in a circular cylindrical form or rectangular cylindrical form. Moreover, a support stand, which is movable downwardly, is provided at a lower portion of the bottomless mold.

When silicon raw materials are charged into a copper mold formed as a melt container and an alternating current is applied to a high-frequency induction coil, since the strip-shaped elements forming the mold are electrically separated from each other, a current in each element forms a loop, with which a current flowing along the inner wall side of the mold create a magnetic field inside the mold, whereby silicon raw materials in the mold can be heated and melted. The silicon raw materials in the mold are melted without contacting the mold by receiving a force inwards and in the direction normal to the molten silicon surface, the force produced through the interaction of a current flowing along the molten silicon surface and a magnetic field created by a current flowing along the mold inner wall.

In this way, when a support stand supporting the molten silicon at a lower portion is moved downward while melting silicon raw materials in the mold, an induction field is decreased as the support stand gets away from the lower end of the high-frequency induction coil, and thus, the amount of heat generated from the coil is reduced along with the reduction of the generation current, and thus solidification of the molten silicon is allowed to progress upwards at the bottom portion of the molten silicon (unidirectional solidification).

By charging raw materials continuously from above the mold to continue melting and solidifying the silicon with the support stand moving downward, a polycrystalline silicon ingot can be cast continuously, while allowing unidirectional solidification of the molten silicon. Why unidirectional solidification is adopted, when the silicon melt is solidified to yield an ingot, is to increase the crystal grain size and prevent cracking caused by a volume expansion associated with the solidification.

It is noted that a polycrystalline silicon produced by an electromagnetic casting method typically has a higher concentration of copper than other impurities in a crystal due to the use of a copper mold. This is considered because copper introduced into the atmosphere is diffused from the outer periphery and migrated into the inside of the ingot due to the proximity of the ingot to the copper mold. Metallic impurities forming a trap (capture) level cause recombination of photo-generated carriers to annihilate the carriers, and thus, the conversion efficiency (a proportion of a convertible energy into an electric energy to be taken out to an incident light energy) at the time of a solar cell form is reduced.

“Impurities in Silicon Solar Cells”, IEEE TRANSACTIONS ON ELECTRON DEVICES, Vol. ED-27, No. 4, p682, Apr. 1980, JOHN RANSFORD DAVIS, JR. et al. describes a relationship between the concentration of metallic impurities and the conversion efficiency of p-type and n-type silicon at the time of a solar cell form. The lower limit of the concentration affecting the conversion efficiency is varied markedly depending on the kind and the conductivity type (p-type or n-type) of metal. According to this literature (FIGS. 4 and 5), copper has a smaller effect on the conversion efficiency of a solar cell, compared with many other metals, but an increase of copper concentration in a crystal caused by use of a copper mold is a problem which should be improved especially for further enhancing the quality of polycrystalline silicon used as a substrate material of a solar cell.

### SUMMARY OF THE INVENTION

An object of the present invention, which has been achieved in view of the circumstances above, is to suppress a copper contamination of the silicon ingot incurred by a cold copper mold and provide an electromagnetic casting method of a silicon ingot suitable as a starting material of the substrate material of a solar cell.

In order to solve the above problems, the present inventors examined the concentration of the copper that is contained in a silicon ingot and the effect of the copper concentration on the conversion efficiency at the time of a solar cell form made with a wafer cut from the silicon ingot as the substrate by extensively changing the length of a part of mold positioned below the lower end of an induction coil (in the mold, the length of a part thereof situated below the lower end of an induction coil), the length being considered to affect the increase of copper concentration in the crystal.

As a result, it was found that the copper contamination of the silicon ingot can be suppressed by reducing the length of the part of mold positioned below the lower end of the coil (in other words, by reducing the area of a portion where the copper mold is proximate to the silicon ingot) to reduce the diffusion of copper from the outer periphery of the silicon ingot toward the inside thereof Further, it was also confirmed that the conversion efficiency at the time of a solar cell form could be maintained at a high level along with the reduction of the copper contamination.

The present invention is achieved based on such findings, and the summary thereof lies in an electromagnetic casting method of a silicon ingot described below.

That is, the present invention is directed to an electromagnetic casting method of a silicon ingot in which a polycrystalline silicon ingot is continuously cast by charging silicon raw materials into a bottomless cold copper mold, melting the silicon raw materials using electromagnetic induction, and pulling down to solidify the molten silicon, wherein the length of a part of mold positioned below a lower end of an induction coil surrounding the copper mold is adjusted in the range of more than 40 mm to 180 mm or less.

Here, the length of “a part of mold positioned below a lower end of the induction coil” is the length of a part of mold L_{M} indicated by an arrow in FIG. 1 described below. Hereinbelow, this length of a part of mold L_{M} is described as “length of copper mold below the coil”.

In the electromagnetic casting method of a silicon ingot of the invention, it is desirable to adopt an embodiment in which the polycrystalline silicon ingot to be cast has a square or rectangular cross section with the length of one of sides being 322 mm or more and 530 mm or less.

Moreover, the electromagnetic casting method of a silicon ingot of the invention (including the above embodiment) is particularly effective when a polycrystalline silicon to be cast is n-type.

### ADVANTAGEOUS EFFECTS OF INVENTION

According to the electromagnetic casting method of a silicon ingot of the invention, a silicon ingot, which is suitable as a starting material of a substrate material of a solar cell, can be produced by suppressing a copper contamination of the silicon ingot incurred by a cold copper mold upon production of a polycrystalline silicon ingot.

### BRIEF DESCRIPTION OF THE DRAWINGS

FIG. 1 is a vertical sectional view showing a schematic configuration of a major portion of electromagnetic casting apparatus suitable for applying an electromagnetic casting method of a silicon ingot of the invention.

FIG. 2 is a graph showing a result of example indicating a relationship between the length of copper mold below the coil and a copper concentration in a silicon ingot.

FIG. 3 is a graph showing a result of example indicating a relationship between the length of copper mold below the coil and the conversion efficiency at the time of a solar cell form.

### DETAILED DESCRIPTION OF THE PREFERRED EMBODIMENTS

The electromagnetic casting method of a silicon ingot of the invention is based on the premise that, in this electromagnetic casting method, a polycrystalline silicon ingot is continuously cast by charging silicon raw materials into a cold bottomless copper mold, melting the silicon raw materials using electromagnetic induction, and pulling down to solidify the molten silicon.

Such an electromagnetic casting method is taken as the premise because upon the production of polycrystalline silicon to be used as a substrate material of a solar cell, molten silicon can be cast in the mold with almost no contact with the mold, and thus a silicon ingot, which is not contaminated with metal from the mold and capable of favorably maintaining the conversion efficiency, can be produced. A production cost can also be significantly reduced because there is no need to use a high purity material as a material of the mold and a casting can be continuously performed.

The electromagnetic casting method of the invention is characterized in that the length of copper mold below the coil (that is, the length of a part of the mold positioned below a lower end of an induction coil surrounding the copper mold) is adjusted in the range of more than 40 mm to 180 mm or less.

In the electromagnetic casting method of the invention, the length of copper mold below the coil is adjusted in a predetermined range so as to suppress diffusion and mixing of copper from the outer periphery of the silicon ingot that is proximate to the copper mold, toward the inside of the ingot.

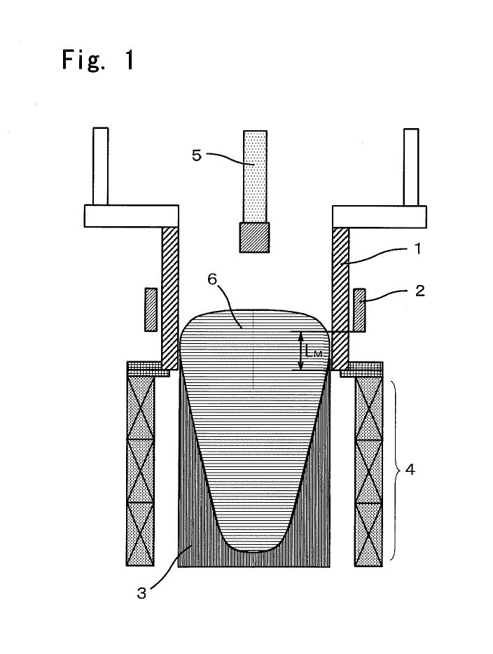

FIG. 1 is a vertical sectional view showing a schematic configuration example of a major portion of electromagnetic casting apparatus suitable for applying an electromagnetic casting method of a silicon ingot of the invention. As shown in FIG. 1, the apparatus has a copper bottomless cold mold 1 and an induction coil 2 surrounding the mold 1, and below the induction coil 2, a heat retention cylinder 4 for heating a solidified silicon ingot 3 to prevent abrupt cooling is installed. Furthermore, in this example, the apparatus has a plasma torch 5 for generating a plasma arc as a heating source. A plasma torch 5 is installed above molten silicon 6 so as to be movable up and down.

In FIG. 1, the length indicated by marking both ends with an arrow is the length of copper mold L_{M} below a coil. In the electromagnetic casting method of the invention, the length of copper mold below the coil is adjusted in the range of more than 40 mm to 180 mm or less to suppress diffusion and migration of copper from the outer periphery toward the inside of a silicon ingot 3 proximate to the copper mold 1.

The length of copper mold below the coil is set to more than 40 mm because a hole is highly likely to be generated in a solid layer (hereinafter, referred to as “a shell”) on the outer periphery of an ingot at or below this length of copper mold, thereby increasing a risk of a melt spill. As the length of copper mold below the coil is reduced, the area of a portion heated to a high temperature can be reduced to decrease an emission source of copper, but particularly in the case where a silicon ingot to be cast has a later described square or rectangular cross section having a length of one side of 322 mm or more and 530 mm or less, the lower limit of the length of copper mold below the coil is more than 40 mm.

On the other hand, the upper limit of the length of copper mold below the coil is set to 180 mm based on a result from an example described later, because the length of copper mold exceeding 180 mm increases the area of a portion of ingot proximate to the mold, thereby enhancing an increasing tendency of copper contamination level in the ingot and also showing a distinct declining tendency of the conversion efficiency.

In addition to this, the upper limit of the length of copper mold below the coil is desirably set to 180 mm at most in consideration of an n-type polycrystalline silicon ingot which would be prevalent in the future. In recent years, a technology for producing n-type polycrystalline silicon using electromagnetic casting, which realizes the high conversion efficiency with no segregation of dopant has been developed. This n-type polycrystalline silicon is more susceptible to a copper contamination than a p-type polycrystalline silicon.

In the electromagnetic casting method of a silicon ingot of the invention, as described above, it is desirable to adopt an embodiment in which the polycrystalline silicon ingot to be cast has a square or rectangular cross section with the length of one of sides being 322 mm or more and 530 mm or less.

In the electromagnetic casting method of the invention, as illustrated in an example described later, a restriction in adjusting the length of copper mold below the coil in the range of more than 40 mm to 180 mm or less is derived from a result of a casting conducted by extensively changing the length of copper mold below the coil in a silicon ingot having a cross section adjusted in this range (that is, the length of one of sides is 322 mm or more and 530 mm or less). Therefore, through the adoption of this embodiment, a melt spill from a hole generated in a shell on the outer periphery of the ingot and an increasing tendency of copper contamination level in the ingot can be suppressed effectively by adjusting the length of copper mold below the coil in a predetermined range.

Even if one of sides of the ingot has a length shorter than the range of 322 mm or more and 530 mm or less, as a matter of course, the length of copper mold below the coil is adjusted in a range of more than 40 mm to 180 mm or less. According to an electromagnetic casting method of the invention, a melt spill from a hole generated in a shell on outer periphery of an ingot and an increasing tendency of copper contamination in the ingot can be suppressed effectively.

The electromagnetic casting method of a silicon ingot of the invention (including the above embodiment) is particularly effective when a polycrystalline silicon to be cast is n-type.

According to the literature of JOHN RANSFORD DAVIS et al., cited above, the lower limit of the copper concentration affecting the conversion efficiency is varied significantly depending on the conductivity type (p-type or n-type) of silicon, and the lower limit of the copper concentration in p-type silicon is in the order of 10¹⁷ atoms/cm³ (FIG. 4 in the literature cited above), whereas that in an n-type silicon is in the order of 10¹⁶ atoms/cm³ (FIG. 5 in the literature cited above), indicating that the lower limit of the copper concentration in n-type silicon is lower than by about one order of magnitude. In other words, the conversion efficiency is more susceptible to a copper contamination in n-type silicon. Therefore, the electromagnetic casting method of a silicon ingot of the invention is particularly effective when a polycrystalline silicon ingot to be cast is n-type. Furthermore, when the present embodiment is applied, it is desirable that the length of copper mold below the coil is adjusted to be a shorter side within the above specified range to further reduce a copper contamination.

### Examples

By using an electromagnetic casting apparatus of a silicon ingot having a schematic configuration example illustrated in FIG. 1 above, a silicon ingot having a size of cross section of 345 mm×505 mm and a length of 7 m was produced by extensively changing the length of copper mold below the coil to examine the concentration of copper included in an ingot and the conversion efficiency of a solar cell formed with a wafer cut from the silicon ingot as a substrate. It is noted that, in a conventional electromagnetic casting method, the length of copper mold below the coil is around 200 mm. Moreover, in an electromagnetic casting, a plasma heating using a plasma torch was used in combination.

The result of the examination is shown in Table 1. In Table 1, “a copper concentration ratio in an ingot” was determined by the following steps: all samples collected from the outer periphery and the central portion at five points in a longitudinal direction of the obtained ingot were melted; a copper concentration in the melted samples were analyzed for Cu using ICP-MS (inductively coupled radiofrequency plasma mass spectroscopy); the results from the analysis were converted into units of atoms/cm³; and the converted results were expressed with 1.0 as a reference indicating a copper concentration at the time that the length of copper mold below the coil was 60 mm Additionally, “conversion efficiency” was determined by measuring current voltage characteristics (I-V characteristics) of a solar cell formed with, as a substrate, a silicon wafer cut from each of the obtained ingots.

TABLE 1

| Length of mold | Copper concentration | Conversion |
|---|---|---|
| below coil (mm) | ratio in ingot (—) | efficiency (%) |
| 220 | 18.2 | 15.5 |
| 200 | 14.6 | 15.8 |
| 180 | 11.8 | 16.14 |
| 160 | 9.6 | 16.31 |
| 140 | 8.4 | 16.29 |
| 120 | 5.8 | 16.31 |
| 100 | 4.2 | 16.42 |
| 80 | 2.0 | 16.53 |
| 60 | 1.0 (Reference) | 16.54 |

| | |
|---|---|
| 40 | Melt spill |

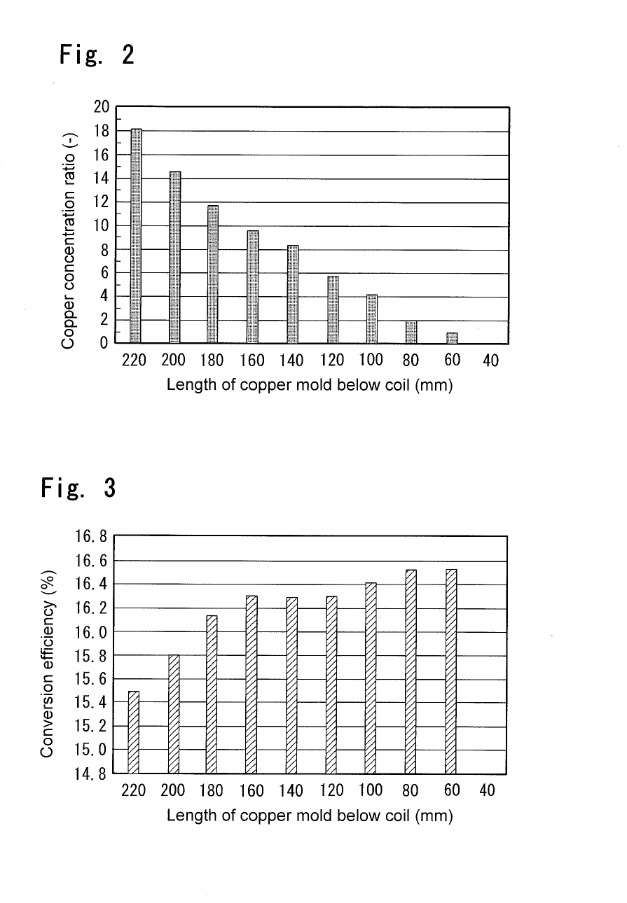

FIGS. 2 and 3 graphically show a result shown in Table 1. FIG. 2 is a graph showing a relationship between the length of copper mold below the coil and a copper concentration in an ingot. FIG. 3 is a graph showing a relationship between the length of copper mold below the coil and the conversion efficiency of a solar cell formed with a wafer cut from an obtained silicon ingot as a substrate. It is noted that, in FIG. 2, a copper concentration ratio in a vertical axis is expressed with 1.0 as a reference indicating a copper concentration when the length of copper mold below the coil is 60 mm. In FIGS. 2 and 3, examination data were not obtained because of melt spill when the length of copper mold below the coil was 40 mm.

As shown in FIG. 2, the length of copper mold below the coil and a copper concentration in an ingot were correlated with each other, and the copper concentration (that is, copper contamination level) is increased as the length of copper mold below the coil is increased. Particularly, when the length of copper mold below the coil exceeds 180 mm, an increasing tendency of copper contamination level is enhanced. On the other hand, the lower limit of the length of copper mold below the coil is restricted in a range where no melt spill is caused.

Moreover, as shown in FIG. 3, the length of copper mold below the coil and the conversion efficiency at the time of a solar cell form were also correlated with each other, and the conversion efficiency shows a declining tendency as the length of copper mold below the coil is increased. Also in this case, the conversion efficiency shows a change in its declining tendency at the point where the length of copper mold below the coil exceeds 180 mm so that the declining tendency is further intensified.

In consideration of the results shown in FIGS. 2 and 3 together, it is thought appropriate that the upper limit of the length of copper mold below the coil is set to 180 mm, at a length longer than which, the increasing tendency of copper contamination level as well as the declining tendency of conversion efficiency are further intensified. On the other hand, the lower limit of the length of copper mold below the coil should appropriately be more than 40 mm, at which no melt spill is caused.

The examples described above verified that a copper contamination of a silicon ingot can be reduced by decreasing the length of copper mold below the coil, a risk of melt spill can be avoided and the conversion efficiency can be kept in a high level by suppressing a copper contamination of a silicon ingot before the copper concentration shows a further increasing tendency, by adjusting the length of copper mold below the coil in the range of more than 40 mm to 180 mm or less.

According to the electromagnetic casting method of a silicon ingot of the invention, a polycrystalline silicon ingot, which is suitable as a starting material of a substrate material of a solar cell, can be produced by suppressing a copper contamination of the silicon ingot incurred by a copper cold mold. Therefore, the present invention can be effectively utilized in a field of producing a solar cell, thereby greatly contributing to a development of a natural energy utilization technology.

What is claimed is:

1. An electromagnetic casting method of a silicon ingot for continuously casting a polycrystalline silicon ingot by charging silicon raw materials into a cold bottomless copper mold, melting the silicon raw materials using electromagnetic induction, and pulling down the molten silicon for solidification,
wherein the length of a part of copper mold positioned below a lower end of an induction coil surrounding the copper mold is adjusted in the range of more than 40 mm to 180 mm or less.

2. The electromagnetic casting method of a silicon ingot according to claim 1, wherein the polycrystalline silicon ingot to be cast has a square or rectangular cross section with the length of one of sides being 322 mm or more and 530 mm or less.

3. The electromagnetic casting method of a silicon ingot according to claim 1, wherein the polycrystalline silicon to be cast is n-type.

4. The electromagnetic casting method of a silicon ingot according to claim 2, wherein the polycrystalline silicon to be cast is n-type.
